(19) United States
(12) Patent Application Publication
(10) Pub. No.: US 2010/0295075 A1
(43) Pub. Date: Nov. 25, 2010

(54) DOWN-CONVERTED LIGHT EMITTING DIODE WITH SIMPLIFIED LIGHT EXTRACTION

(75) Inventors: Terry L. Smith, Roseville, MN (US); Tommie W. Kelley, Shoreview, MN (US); Michael A. Haase, St. Paul, MN (US); Catherine A. Leatherdale, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/746,898

(22) PCT Filed: Nov. 7, 2008
(86) PCT No.: PCT/US08/82766

§ 371 Date: Aug. 10, 2010

Related U.S. Application Data
(60) Provisional application No. 61/012,604, filed on Dec. 10, 2007.

(51) Int. Cl. H01L 33/40; H01L 21/30

(52) U.S. Cl. 257/98; 438/29; 257/E33.074; 257/E21.211

(57) ABSTRACT

A wavelength converted light emitting diode (LED) device has an LED having an output surface. A multilayer semiconductor wavelength converter is optically bonded to the LED. At least one of the LED and the wavelength converter is provided with light extraction features.

### FIELD OF THE INVENTION

The invention relates to light emitting diodes, and more particularly to a light emitting diode (LED) that includes a wavelength converter for converting the wavelength of light emitted by the LED.

### BACKGROUND

Wavelength converted light emitting diodes (LEDs) are becoming increasingly important for illumination applications where there is a need for light of a color that is not normally generated by an LED, or where a single LED may be used in the production of light having a spectrum normally produced by a number of different LEDs together. One example of such an application is in the back-illumination of displays, such as liquid crystal display (LCD) computer monitors and televisions. In such applications there is a need for substantially white light to illuminate the LCD panel. One approach to generating white light with a single LED is to first generate blue light with the LED and then to convert some or all of the light to a different color. For example, where a blue-emitting LED is used as a source of white light, a portion of the blue light may be converted using a wavelength converter to yellow light. The resulting light, a combination of yellow and blue, appears white to the viewer.

In some approaches, the wavelength converter is a layer of semiconductor material that is placed in close proximity to the LED, so that a large fraction of the light generated within the LED passes into the converter. There remains an issue, however, where it is desired that the wavelength converted be attached to the LED die. Typically, semiconductor materials have a relatively high refractive index while the types of materials, such as adhesives, that would normally be considered for attaching the wavelength converter to the LED die have a relatively low refractive index. Consequently, the reflective losses are high due to the high degree of total internal reflection at the interface between relatively high index semiconductor LED material and the relatively low index adhesive. This leads to inefficient coupling of the light out of the LED and into the wavelength converter.

There is a need for alternative approaches to coupling a semiconductor wavelength converter to a LED that can reduce the internal reflection losses at the LED. There is also a need to ensure that the down-converted light is efficiently extracted from the converter.

### SUMMARY OF THE INVENTION

One embodiment of the invention is directed to a wavelength converted light emitting diode (LED) device having an LED having an output surface. A multilayer semiconductor wavelength converter is optically bonded to the LED. At least one of the LED and the wavelength converter is provided with light extraction features.

Another embodiment of the invention is directed to a semiconductor wavelength converter device that has a multilayer semiconductor wavelength converter. The wavelength converter has light extraction features. A removable protection layer is provided on a first side of the wavelength converter. A second side of the wavelength converter is flat for optical bonding to another semiconductor element.

Another embodiment of the invention is directed to a method of making wavelength converted, light emitting diodes. The method includes providing a light emitting diode (LED) wafer comprising a set of LED semiconductor layers disposed on a substrate and providing a multilayer semiconductor wavelength converter wafer configured to be effective at converting wavelength of light generated within the LED layers. The converter wafer is optically bonded to the LED wafer to produce an LED/converter wafer. Individual converted LED dies are separated from the LED/converter wafer.

The above summary of the present invention is not intended to describe each illustrated embodiment or every implementation of the present invention. The following figures and detailed description more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 schematically illustrates an embodiment of a wavelength-converted light emitting diode (LED) according to principles of the present invention;

FIG. 2 schematically illustrates an embodiment of a multilayer semiconductor wavelength converter;

FIGS. 3A and 3B schematically illustrate total internal reflection in a semiconductor element and the use of light extraction features to reduce the effects of total internal reflection;

FIG. 4 schematically illustrates another embodiment of a wavelength-converted LED according to principles of the present invention;

FIG. 5 schematically illustrates another embodiment of a wavelength-converted LED according to principles of the present invention;

FIG. 6 schematically illustrates another embodiment of a wavelength-converted LED according to principles of the present invention;

FIG. 7 schematically illustrates another embodiment of a wavelength-converted LED using an intermediate layer between the wavelength converter and the LED, according to principles of the present invention;

FIG. 8 schematically illustrates another embodiment of a wavelength-converted LED in which a scattering layer operates as a light extraction feature, according to principles of the present invention;

FIGS. 9A-9D schematically illustrate fabrication steps for forming a scattering layer as a light extraction feature according to principles of the present invention;

FIGS. 10A-10F schematically illustrate fabrication steps for forming a wavelength converted LED device according to principles of the present invention;

FIG. 11 schematically illustrates an embodiment of a wavelength converter provided with a light extraction feature, according to principles of the present invention;

FIGS. 12A-12D schematically illustrate wafer level fabrication steps, according to principles of the present invention; and

FIG. 13 schematically illustrates a wavelength converted LED having two separate light extraction features.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present invention is applicable to light emitting diodes that use a wavelength converter to convert the wavelength of at least a portion of the light emitted by the LED to a different, typically longer, wavelength. The invention is particularly well suited to a method of efficiently using semiconductor wavelength converters with blue or UV LEDs, which are usually based on a nitride material such as AlGaInN. More particularly, some embodiments of the invention are directed to directly bonding a multilayer, semiconductor wavelength converter to a LED. Assembly of the device may be possible at the wafer level, which greatly reduces manufacturing costs.

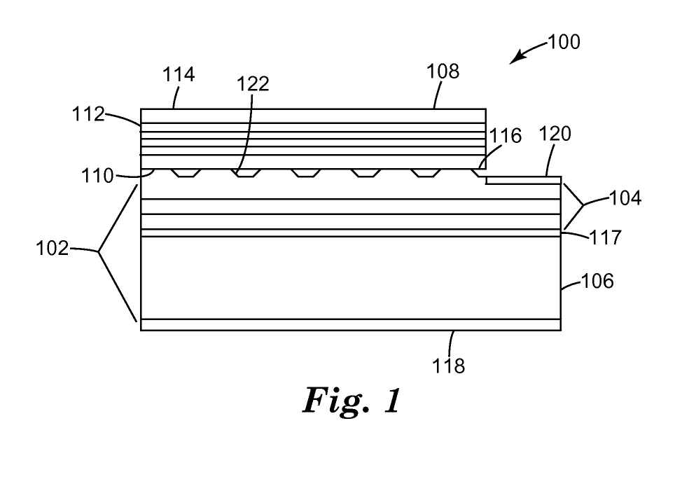

An example of a wavelength-converted LED device 100 according to a first embodiment of the invention is schematically illustrated in FIG. 1. The device 100 includes an LED 102 that has a stack of LED semiconductor layers 104 on an LED substrate 106. The LED semiconductor layers 104 may include several different types of layers including, but not limited to, p- and n-type junction layers, light emitting layers (typically containing quantum wells), buffer layers, and superstrate layers. The LED semiconductor layers 104 are sometimes referred to as epilayers due to the fact that they are typically grown using an epitaxial process. The LED substrate 106 is generally thicker than the LED semiconductor layers 104, and may be the substrate on which the LED semiconductor layers 104 are grown or may be a substrate to which the semiconductor layers 104 are attached after growth. A semiconductor wavelength converter 108 is optically bonded to the upper surface 110 of the LED 102.

Two semiconductor elements are optically bonded together when they are directly bonded by contact, sometimes called wafer bonding, or when they are attached to each other with the distance separating their surfaces being less than an evanescent distance of the light passing from one element to the other. Direct bonding occurs when two different pieces, having flat surfaces, are brought into physical contact. The flatness of the material surfaces determines the strength of the bond: the flatter the surface, the stronger the bond. An advantage of the direct bond is that there is no intermediate, low refractive index adhesive layer and so the likelihood of total internal reflection may be reduced. In evanescent bonding, a very thin layer of an intermediate material helps in the bonding process. The intermediate material is so thin, however, that light is substantially evanescently coupled from one semiconductor element to the other semiconductor element without total internal reflection, even though the refractive index of the intermediate layer may be low compared with that of the semiconductor elements. In the case of blue LEDs and semiconductor wavelength converters, the evanescent distance separating the two semiconductor elements is significantly less than one quarter of the vacuum wavelength of the light. A more detailed discussion on the thickness of an intermediate layer that permits evanescent coupling is provided below.

While the invention does not limit the types of LED semiconductor material that may be used and, therefore, the wavelength of light generated within the LED, it is expected that the invention will be particularly useful at converting light at the blue or UV portion of the spectrum into longer wavelengths of the visible or infrared spectrum, so the emitted light may appear to be, for example, green, yellow, amber, orange, or red, or, by combining multiple wavelengths, the light may appear to be a mixed color such as cyan, magenta or white. For example, an AlGaInN LED that produces blue light may be used with a wavelength converter that absorbs a portion of the blue light to produce yellow light. If some of the blue light remains unconverted, then the resulting combination of blue and yellow light appears to the viewer to be white.

One suitable type of semiconductor wavelength converter 108 is described in U.S. patent application Ser. No. 11/009,217 and 60/978,304. A multilayered wavelength converter typically employs multilayered quantum well structures based on II-VI semiconductor materials, for example various metal alloy selenides such as CdMgZnSe. In such multilayered wavelength converters, the quantum well structure 112 is engineered so that the band gap in portions of the structure is selected so that at least some of the pump light emitted by the LED 102 is absorbed. The charge carriers generated by absorption of the pump light move into other portions of the structure having a smaller band gap, the quantum well layers, where the carriers recombine and generate light at the longer wavelength. This description is not intended to limit the types of semiconductor materials or the multilayered structure of the wavelength converter.

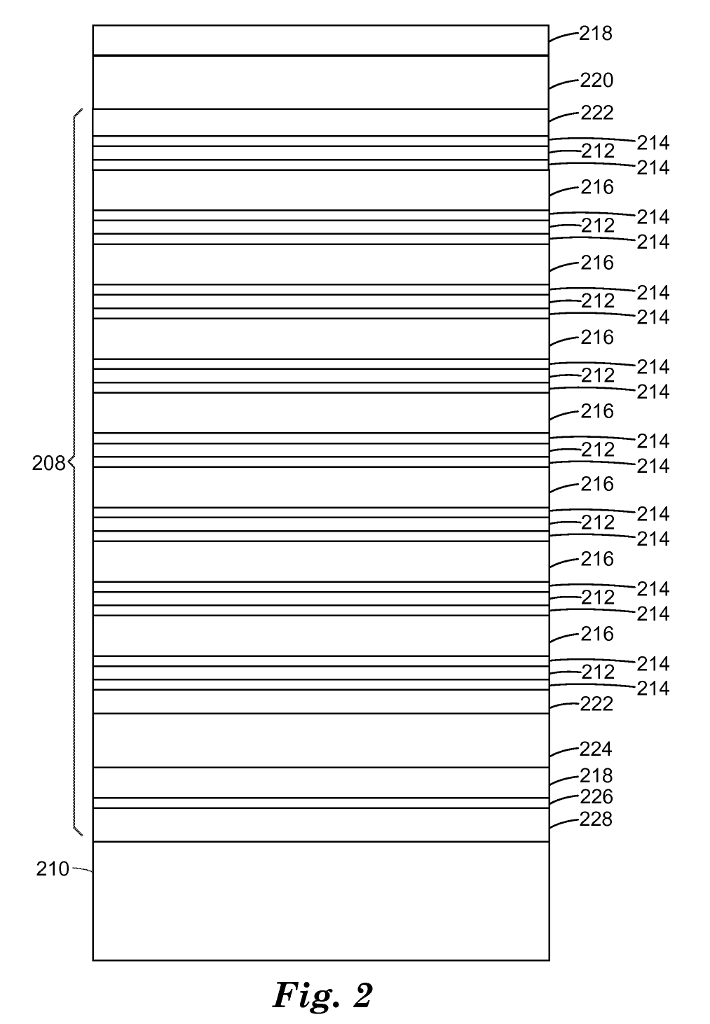

One particular example of a suitable wavelength converter is described in U.S. Application No. 60/978,304. A multilayer, quantum well semiconductor converter 208 was initially prepared on an InP substrate using molecular beam epitaxy (MBE). A GaInAs buffer layer was first grown by MBE on the InP substrate to prepare the surface for II-VI growth. The wafer was then moved through an ultra-high vacuum transfer system to another MBE chamber for growth of the II-VI epitaxial layers for the converter. The details of the as-grown converter 208, complete with substrate 210, are shown in FIG. 2 and summarized in Table I. The table lists the thickness, material composition, band gap and layer description for the different layers in the converter 208. The converter 208 included eight CdZnSe quantum wells 212, each having an energy gap (Eg) of 2.15 eV. Each quantum well 212 was sandwiched between CdMgZnSe absorber layers 214 having an energy gap of 2.48 eV that could absorb the blue light emitted by the LED. The converter 208 also included various window, buffer and grading layers.

TABLE I
Details of Wavelength Converter Structure

| Layer | | Thickness | Band Gap | |
|---|---|---|---|---|
| No. | Material | (\acute{Å}) | (eV) | Description |
| 212 | Cd_{0.48}Zn_{0.52}Se | 31 | 2.15 | Quantum well |
| 214 | Cd_{0.38}Mg_{0.21}Zn_{0.41}Se | 80 | 2.48 | Absorber |
| 216 | Cd_{0.38}Mg_{0.21}Zn_{0.41}Se: Cl | 920 | 2.48 | Absorber |
| 218 | Cd_{0.22}Mg_{0.45}Zn_{0.33}Se | 1000 | 2.93 | Window |
| 220 | Cd_{0.22}Mg_{0.45}Zn_{0.33}Se- | 2500 | 2.93-2.48 | Grading |
| | Cd_{0.38}Mg_{0.21}Zn_{0.41}Se | | | |
| 222 | Cd_{0.38}Mg_{0.21}Zn_{0.41}Se: Cl | 460 | 2.48 | Absorber |
| 224 | Cd_{0.38}Mg_{0.21}Zn_{0.41}Se- | 2500 | 2.48-2.93 | Grading |
| | Cd_{0.22}Mg_{0.45}Zn_{0.33}Se | | | |
| 226 | Cd_{0.39}Zn_{0.61}Se | 44 | 2.24 | |
| 228 | Ga_{0.47}In_{0.53}As | 1900 | 0.77 | Buffer |

The back surface of the InP substrate 210 may be mechanically lapped and removed with a solution of 3HCl:1H₂O after the wavelength converter 208 is optically bonded to the LED. This etchant stops at the GaInAs buffer layer 228. The buffer layer 228 may subsequently be removed in an agitated solution of 30 ml ammonium hydroxide (30% by weight), 5 ml hydrogen peroxide (30% by weight), 40 g adipic acid, and 200 ml water, leaving only the II-VI semiconductor wavelength converter 208 bonded to the LED.

The upper and lower surfaces and of the semiconductor wavelength converter 108 may include different types of coatings, such as light filtering layers, reflectors or mirrors, for example as described in U.S. patent application Ser. No. 11/009,217. The coatings on either of the surfaces and may also include an anti-reflection coating.

Coatings may be applied to either the LED 102 or the wavelength converter 108 to improve adhesion at the optical bond These coatings may include, for example, TiO₂, Al₂O₂, SiO₂, Si₃N₄ and other inorganic or organic materials. Surface treatment methods may also be performed to improve adhesion, for example, corona treatment, exposure to O₂ or Ar plasma, exposure to an Ar ion beam, and exposure to UV/ozone.

In some embodiments the LED semiconductor layers 104 are attached to the substrate 106 via an optional bonding layer 117, and electrodes 118 and 120 may be respectively provided on the lower and upper surfaces of the LED 102. This type of structure is commonly used where the LED is based on nitride materials: the LED semiconductor layers 104 may be grown on a substrate, for example sapphire or SiC, and then transferred to another substrate 106, for example a silicon or metal substrate. In other embodiments the LED 102 may employ the substrate 106, e.g. sapphire or SiC, on which the semiconductor layers 104 are directly grown.

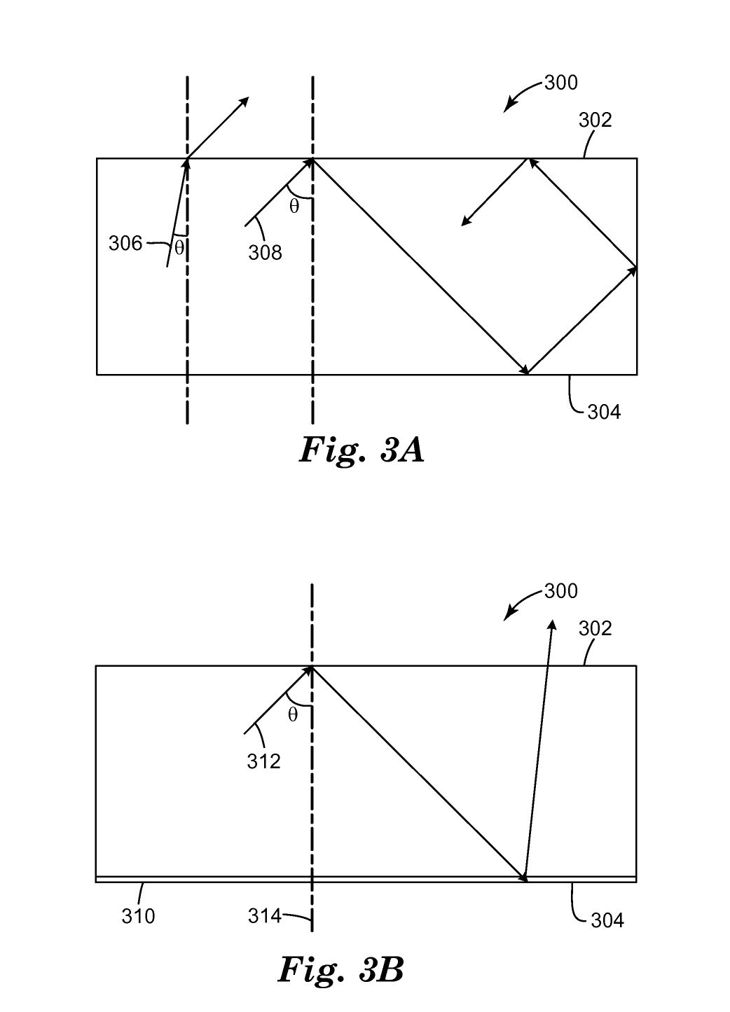

The extraction of light from a semiconductor element 300 such as an LED or semiconductor wavelength converter is now discussed with reference to FIGS. 3A and 3B. In FIG. 3A, the semiconductor element 300 is assumed to have a refractive index of nₛ, while the external environment has a refractive index of nₑ. Some of the light incident at the surface 302 of the element is transmitted if the incident angle, θ, is less than the critical angle, θ_{c}=sin⁻¹ (nₑ/nₛ), for example ray 306. If the angle of incidence is greater than the critical angle, then the light is totally internally reflected, for example ray 308. Typically, semiconductor elements are fabricated using epitaxy and lithographic techniques with the result that their surfaces are parallel. Consequently, the light lying outside the extraction cone, i.e. outside that cone of light directions that have an angle of incidence less than the critical angle, is trapped within the semiconductor element by total internal reflection.

Extraction features 310, shown schematically in FIG. 3B may be used to change the direction of light within the semiconductor element 300. Extraction features 310 may include features on the surface of the element 300 or within the semiconductor element 300 itself. Thus, an exemplary light ray 312, which is totally internally reflected at the lower surface 304 is also changed in direction, so that it is incident on the upper surface 302 at an angle less than the critical angle, and so light ray 312 escapes from the element 300. Thus, the use of extraction features may enhance the extraction of light from either/or the LED and the wavelength converter. An extraction feature is any type of feature intentionally provided to change the direction of at least a fraction of the light within the semiconductor element 300 relative to an axis 314 of the element 300, so that the light extraction is enhanced. For example, an extraction feature may be texture on the surface of the element or scattering/diffusing particles disposed within the element.

In the embodiment illustrated in FIG. 1, the LED 102 is provided with an extraction feature 122 in the form of a textured surface. The textured surface 122 may be in any suitable form that provides portions of the surface that are non-parallel to the planar structure of the LED 102 or wavelength converter 108. For example, the texture may be in the form of holes, bumps, pits, cones, pyramids, various other shapes and combinations of different shapes, for example as are described in U.S. Pat. No. 6,657,236. The texture may include random features or non-random periodic features. Feature sizes on the textured surface 122 are generally submicron but may be as large as several microns. Periodicities or coherence lengths may also range from submicron to micron scales. In some cases, the textured surface may comprise a moth-eye surface such as described by Kasugai et al. in Phys. Stat. Sol. Volume 3, page 2165, (2006) and U.S. patent application Ser. No. 11/210,713. The textured surface 122 also contains flat portions that are parallel to the wavelength converter 108 and which are directly bonded to the wavelength converter 108. Thus, in this embodiment, light can escape from the LED 102 into the wavelength converter 108 at those portions of the textured surface 122 that are directly bonded to the wavelength converter 108.

A surface may be textured using various techniques such as etching (including wet chemical etching, dry etching processes such as reactive ion etching or inductively coupled plasma etching, electrochemical etching, or photoetching), photolithography and the like. A textured surface may also be fabricated through the semiconductor growth process, for example by rapid growth rates of a non-lattice matched composition to promote islanding, etc. Alternatively, the growth substrate itself can be textured prior to initiating growth of the LED layers using any of the etching processes described previously. Without a textured surface, light is efficiently extracted from an LED only if its propagation direction within the LED lies inside the angular distribution that permits extraction. This angular distribution is limited, at least in part, by total internal reflection of the light at the surface of the LED's semiconductor layers. Since the refractive index of the LED semiconductor material is relatively high, the angular distribution for extraction becomes relatively narrow. The provision of the textured surface 122 allows for the redistribution of propagation directions for light within the LED 102, so that a higher fraction of the light may be extracted from the LED 102 into the wavelength converter 108.

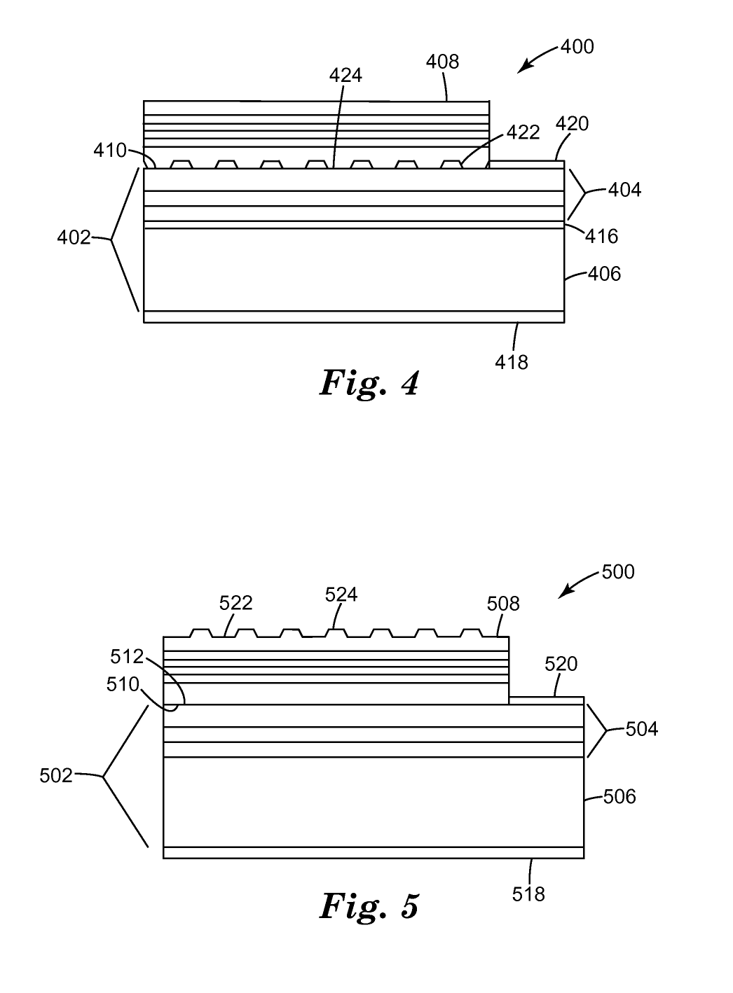

Another embodiment of the invention is schematically illustrated in FIG. 4. A wavelength-converted LED device 400 includes an LED 402 that has LED semiconductor layers 404 over a substrate 406. In the illustrated embodiment, the LED semiconductor layers 404 are attached to the substrate 406 via an optional bonding layer 416. A lower electrode layer 418 may be provided on the surface of the substrate 406 facing away from the LED layers 404. An upper electrode 420 is provided on the upper side of the LED 402.

The lower surface 410 of a wavelength converter 408 is directly bonded to the LED 402. In this embodiment the lower surface 410 of the wavelength converter 408 comprises a textured surface 422, with some texture at angles to redirect light within the wavelength converter 408.

Since the refractive indices of the LED 402 and wavelength converter 408 are relatively close in magnitude, then the extraction cone in the LED 402 has a large angle, and light can escape from the LED 402 into the wavelength converter 408 through those portions 424 of the lower surface 410 directly bonded to the LED 402. If the refractive index of the wavelength converter 408 is higher than that of the LED 402, then the extraction cone has an apex angle of 180°, and there is no total internal reflection within the LED 402, irrespective of incident angle. Thus, a large fraction of the light can be extracted from the LED 402 into the wavelength converter. In addition, the textured surface 422 may be used to redirect light within the wavelength converter 408, thus reducing the amount of light trapped within the wavelength converter 408 by total internal conversion.

Another embodiment of the invention is schematically illustrated in FIG. 5. A wavelength-converted LED device 500 includes an LED 502 that has LED layers 504 over an LED substrate 506. The upper surface 510 of the LED 502 is directly bonded to the lower surface 512 of a wavelength converter 508. The LED 502 is provided with electrodes 518 and 520. In this case, the upper surface 522 of the wavelength converter 508 is provided with light extraction features in the form of a textured surface 524. The textured surface 524 may be formed using any of the techniques described above.

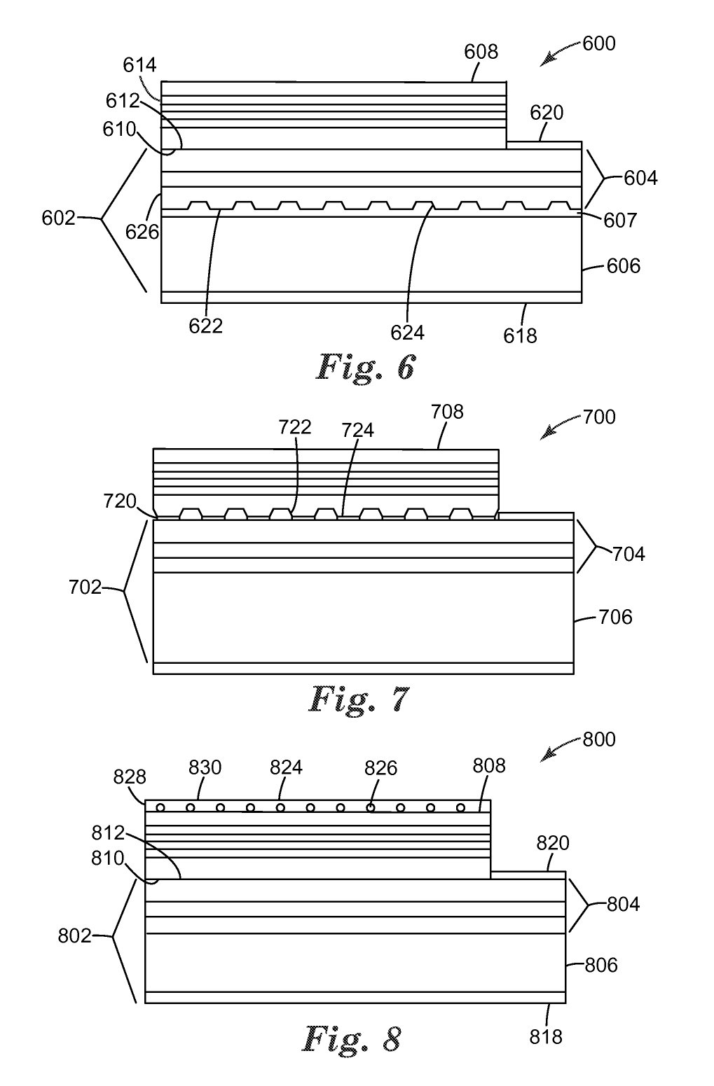

Another embodiment of the invention is schematically illustrated in FIG. 6. A wavelength-converted LED device 600 includes an LED 602 that has LED layers 604 attached to an LED substrate 606 via bonding layer 607. The upper surface 610 of the LED 602 is directly bonded to the lower surface 612 of a layered semiconductor wavelength converter 608. The LED 602 is provided with electrodes 618 and 620. In this case, the lower surface 622 of the LED layers 604 is provided with light extraction features in the form of a textured surface 624. The bonding layer 607 is metallized so as to reflect light within the LED layers 604, with the result that at least some of the light incident at the metallized bond 607 in a direction that lies outside the angular distribution for extraction may be redirected into the extraction angular distribution. The textured surface 624 may be formed, for example, using any of the techniques discussed above. The metallized bond 607 may also provide an electrical path between the lower LED layer 626 and the LED substrate 606.

Another embodiment of a wavelength converted LED 700 is now described with reference to FIG. 7. This embodiment is somewhat similar to the embodiment illustrated in FIG. 4, except that an evanescently thin intermediate layer 720 is disposed at the optical bond between the wavelength converter 708 and the LED 702. The intermediate layer 720 is sufficiently thin that light evanescently couples from the LED 702 into the wavelength converter 708. As was stated above, the intermediate layer 720 is significantly less than one quarter of a wavelength thick. The practical operating thickness of the intermediate layer 720 is a matter of design choice and depends in part on the wavelength of operation, the refractive indices of the intermediate layer, the LED 702 and the wavelength converter 708, and on the acceptable fraction of light evanescently coupled through the intermediate layer. For example, for high index contrast between the refractive index of the LED 702 and the wavelength converter 708 such that n₁>1.15 n₂ (where n₁ is the refractive index of the LED 720 and n₂ is the refractive index of the intermediate layer 720), and where it is assumed that the light in the LED 702 is emitted isotropically and that one half of the light emitted into the forward cone (towards the intermediate layer) has an evanescent field penetration depth that is greater than the thickness of the intermediate layer 720, it can be shown that the maximum value of the thickness, tₘₐₓ, of the intermediate layer 720 is given by:

$${t}_{max} = \frac{{λ}_{0}}{2 π \sqrt{{( 0.87 {n}_{1} )}^{2} - {n}_{2}^{2}}}$$

where λ₀ is the vacuum wavelength of the light emitted by the LED 702. As an illustrative example, for a GaN-based LED 702, a ZnSe-based wavelength converter 708 (such as that shown in FIG. 2), and a silica intermediate layer 720, the intermediate layer 720 may have a thickness up to around 50 nm under the criteria discussed above.

The intermediate layer 720 may be made of any suitable material that can preserve the flat surface of the LED 702 and the wavelength converter 708 prior to optical bonding. For example, the intermediate layer 720 may be made of an inorganic glass, such as silica or borophosphosilicate glass (BPSG), silicon nitride (Si₃N₄), and other inorganic materials such as titania and zirconia, or may be made of an organic polymer. The material of the intermediate layer 720 may be provided on either the LED 702 or the wavelength converter 708, or both, prior to optically bonding the two elements together. The material of the intermediate layer 720 may be selected to provide a flat, chemically suitable layer for bonding upon contact with another flat surface.

Light can escape through the bonded regions 724 from the LED 702 into the wavelength converter 708. Texture 722 on the lower surface of the wavelength converter 708 redistributes the direction of light propagating within the wavelength converter for increased light extraction.

It will be appreciated that other embodiments of wavelength converted LED may also use an intermediate layer in addition to the embodiment illustrated in FIG. 7.

Another embodiment of a wavelength converted LED device 800 is schematically illustrated in FIG. 8. The device 800 comprises an LED 802 formed of LED semiconductor layers 804 attached to an LED substrate 806. The upper surface 810 of the LED 802 is optically bonded to the lower surface 812 of a multilayer semiconductor wavelength converter 808. Electrodes 818 and 820 are provided on the LED 802.

In this embodiment, the light extraction features 824 include a scattering layer formed by an arrangement of diffusing particles 826 disposed in a high index embedding layer 828 to form upper surface 830 of the wavelength converter 808. The scattering layer 824 may be made by applying a layer of low index nanoparticles 826 to the surface of the semiconductor element, and then burying the particles 826 in a high index embedding layer.

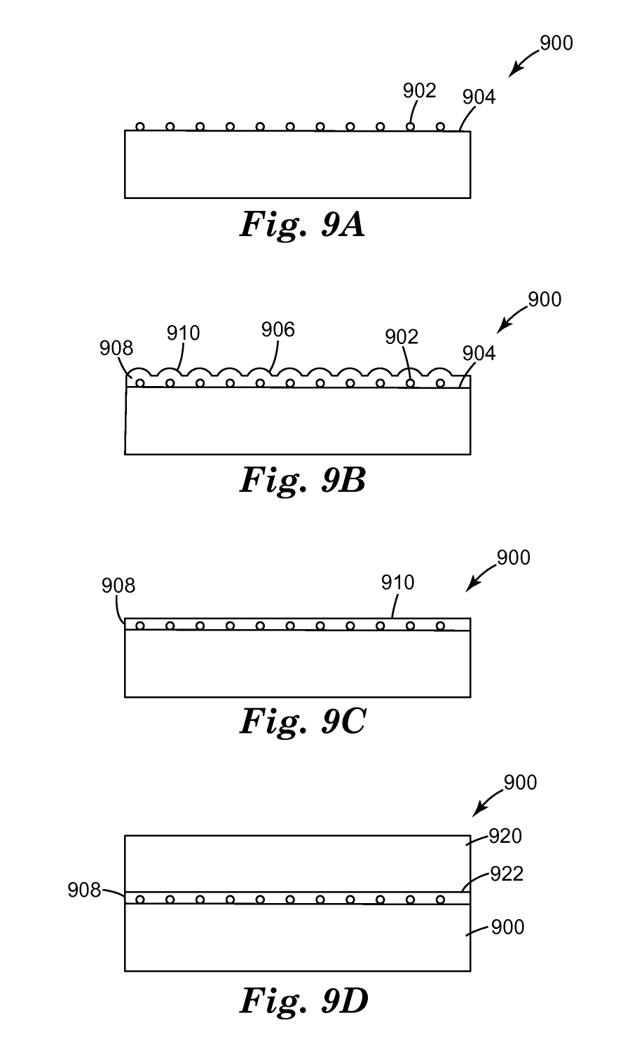

An exemplary process for forming a scattering layer is now described with respect to FIGS. 9A-9D. FIG. 9A shows a semiconductor element 900, which may be any type of semiconductor element, such as an LED or a semiconductor wavelength converter. Nanoparticles 902, typically having a refractive index lower than that of the semiconductor element 900, are applied to the surface 904 of the semiconductor element 900. The particles are typically less than 1000 nm in diameter, and may smaller, for example less than 500 nm or less than 100 nm. The nanoparticles 902 may be formed of any suitable material whose refractive index is different from that of the element 900. Exemplary materials include inorganic materials such as silica, zirconia or indium-tin oxide (ITO) or organic materials such as fluoropolymers like polytetrafluoroethylene (PTFE).

FIG. 9B schematically illustrates an embedding layer 906 deposited over the particles 902 to form the scattering layer 908. The embedding layer 906 may be formed, for example, from a semiconductor material. In some embodiments, it may be advantageous to allow the free passage of light from the semiconductor element 900 to the scattering layer 908 and vice versa, in which case the refractive index of the embedding layer 906 may be selected to be similar, or close to, that of the semiconductor element 900. For example, where the semiconductor element 900 is formed of a II-VI ZnCdSe semiconductor material, the embedding layer 906 may be formed of ZnSe or ZnCdSe material. Where the semiconductor element 900 is an InGaN LED, the embedding layer may be formed of InGaN.

In other embodiments, it may be desired that the refractive index of the embedding layer 908 be different from that of the semiconductor element 900. For example, where the scattering layer 908 is provided on the output side of a wavelength converter, such as is shown in FIG. 8, it may be desired that the refractive index of the embedding layer 906 be higher than that of the wavelength converter. In such a case, the refractive index difference may reduce the amount of light passing back to the wavelength converter from the embedding layer 906 due to total internal reflection at the interface between the embedding layer and the wavelength converter.

The density of nanoparticles 902 on the surface 904 is selected for the desired degree of scattering within the finished device. For example, it may be desired that only about 30% of the surface 904 is covered with nanoparticles, in which case light passing through the remaining 70% of the surface 904 is not directly scattered by the nanoparticles. The light may also be scattered by the outer surface 910 of the embedding layer 906 that may become textured due to the presence of particles. It will be appreciated that other values of particle coverage density may be employed, depending on the particular design of the semiconductor device.

In some embodiments, it may be desired that the outer surface 910 of the scattering layer 908 be flat, for example, when the scattering layer 908 is the layer of the element 900 that forms a direct bond with another element. The outer surface 910, as shown in FIG. 9C, may be polished using chemo-mechanical polishing techniques.

As is shown in FIG. 9D, another semiconductor element 920 may be directly bonded to the scattering layer 908 of the first semiconductor element 900. For example, the first semiconductor element 900 may be an LED while the second semiconductor element 920 is a wavelength converter, or vice versa.

In some embodiments, the nanoparticles are provided close to a material interface within the device's structure. For example, the nanoparticles 902 may be with an evanescent coupling distance of the interface 922 between the scattering layer 908 and the second semiconductor element 920.

It will be appreciated that the above method of providing a scattering layer on a semiconductor element may be performed after the element has been optically bonded to another element. For example, a scattering layer may be provided on a wavelength converter that has already been optically bonded to an LED. In this case embedding layer need not be polished, if such a step is found not to be necessary.

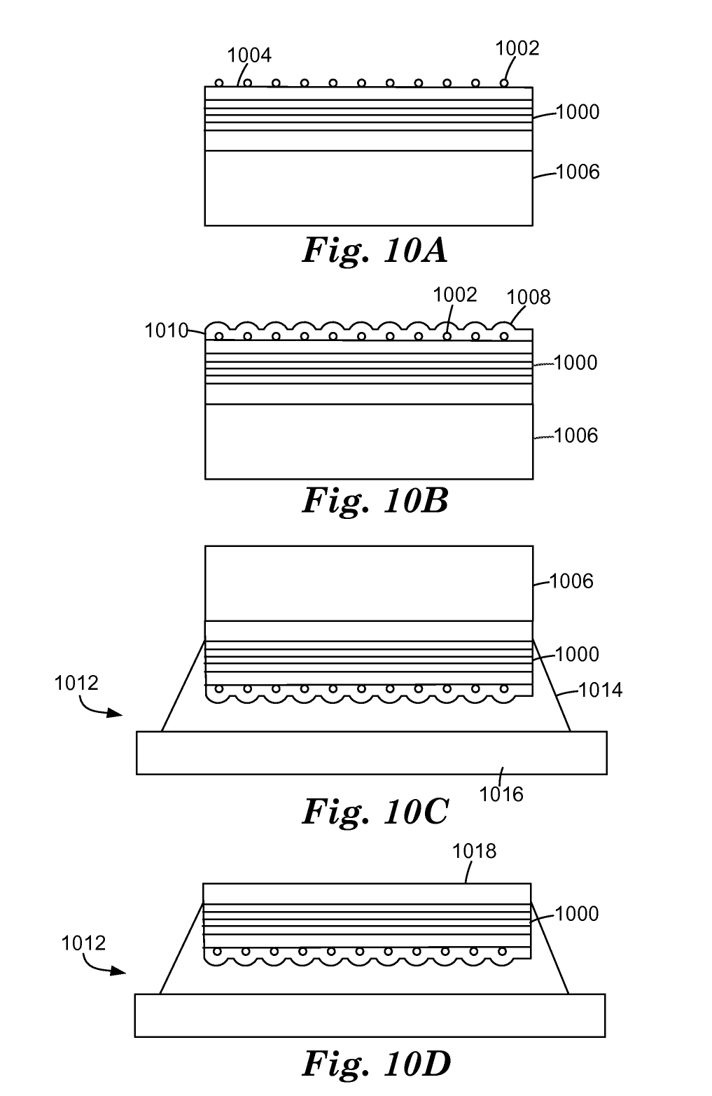

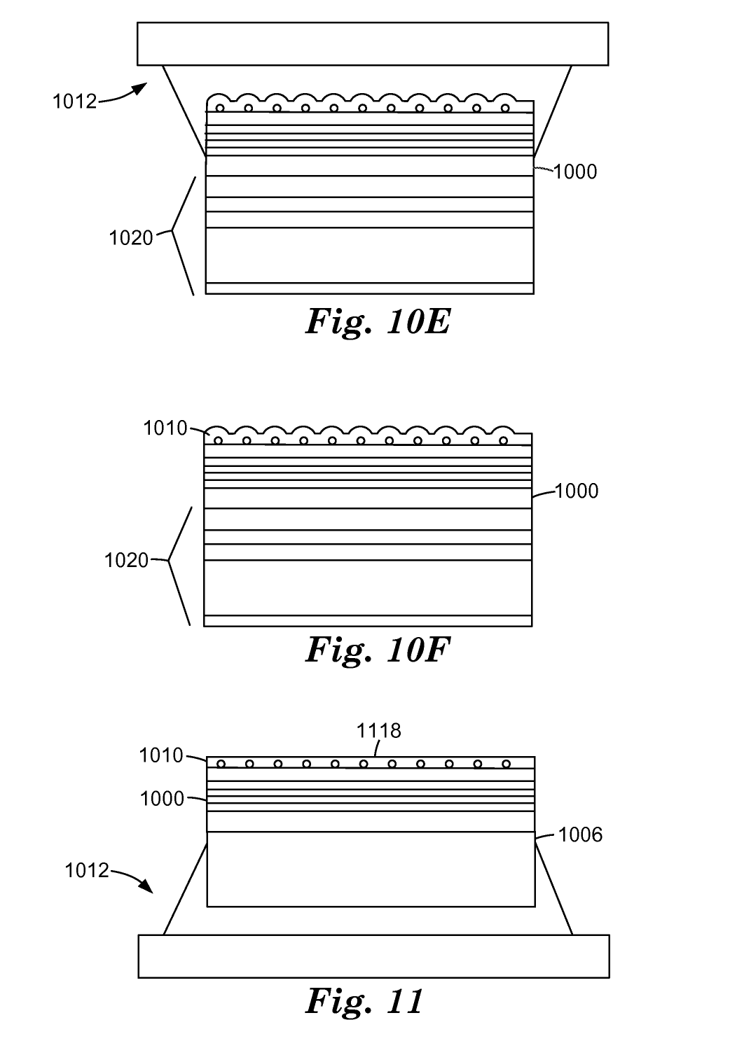

Another method for providing a scattering layer on a semiconductor element is now described with reference to FIGS. 10A-10G. In this embodiment, nanoparticles 1002 are provided over the upper surface 1004 surface of a wavelength converter 1000 that is still attached to a substrate 1006, as shown in FIG. 10A. The surface 1004 is covered with an embedding layer 1008 to form a scattering layer 1010, as shown in FIG. 10B. The wavelength converter is then attached to a removable cover 1012, for example a substrate 1016 and a temporary adhesive material 1014, as shown in FIG. 10C. The substrate may be any suitable type of substrate, for example a microscope slide, a polished silica plate, a silicon wafer or the like. The temporary adhesive material may be any type of adhesive or other material for temporarily attaching the wavelength converter 1000 to the substrate. For example, the temporary adhesive may be a wax, a thermoplastic adhesive such as Crystalbond™ or Wafer-Mount™, obtainable from EMS, Hatfield, Pa., a dissolvable material or other material that is easily removed from the wavelength converter 1000. In this particular embodiment, the removable cover 1012 is attached to the side of the wavelength converter 1000 that has the light extraction features.

The substrate 1006 may then be removed, as shown in FIG. 10D. The exposed surface 1018 of the wavelength converter 1000 may be polished in preparation for optical bonding. The wavelength converter 1000 may then be optically bonded to an LED 1020, as shown in FIG. 10E. The removable cover 1012 may then be removed, as shown in FIG. 10F, to produce a wavelength converted LED device.

It is not necessary that the removable cover 1012 be positioned on the scattering layer side of the wavelength converter, and the removable cover 1012 may also be attached to the substrate side of the wavelength converter 1000, as is schematically illustrated in FIG. 11. In the embodiment illustrated in FIG. 11, the upper surface 1118 of the scattering layer 1010 is polished flat suitable for optically contacting to another surface such as the polished upper surface of an LED.

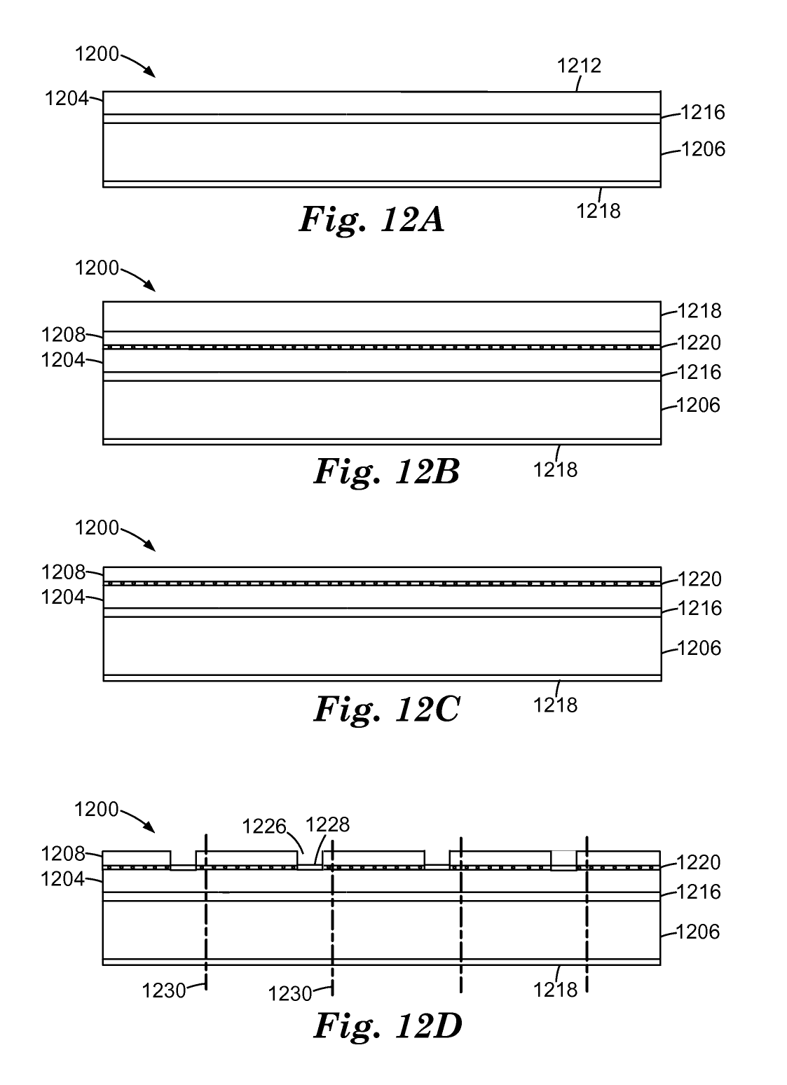

There is no intention to limit the scope of the present disclosure to fabrication at the device level. In fact, the present invention is well suited to fabricating wavelength converted LED devices at the wafer level. One suitable approach to fabricating several wavelength converted LED devices at once, at the wafer level is schematically illustrated in FIG. 12A-12D. FIG. 12A schematically illustrates an LED wafer 1200 having LED semiconductor layers 1204 over an LED substrate 1206. In some embodiments, the LED semiconductor layers 1204 are grown directly on the substrate 1206 and, in other embodiments, the LED semiconductor layers 1204 are attached to the substrate 1206 via an optional bonding layer 1216 (as shown). The upper surface of the LED layers 1204 is a polished surface 1212, suitable for optical contacting to another polished surface. The lower surface of the substrate 1206 may be provided with a metallized layer 1218.

A multilayered semiconductor wavelength converter 1208 wafer, grown on a converter substrate 1218, is optically bonded to the polished surface 1212 of the LED wafer 1200, as is shown in FIG. 12B. Either the LED wafer 1200 or the wavelength converter wafer 1208 may be provided with light extraction features. In the illustrated embodiment, the light extraction features include a scattering layer 1220 on the lower side of the wavelength converter wafer 1208, facing the LED wafer 1200.

The converter substrate 1218 may then be etched away, to produce the bonded wafer structure shown in FIG. 12C.

Vias 1226 are then etched through the wavelength converter 1208 to expose upper surface of the LED wafer 1200, and metallized portions 1228 are deposited on the LED wafer 1200 for use as LED electrodes, as shown in FIG. 12D. The bonded wafer may be cut, for example using a wafer saw, at the dashed lines 1230 to produce separate wavelength converted LED devices. Other methods may be used for separating individual devices from a wafer, for example laser scribing and water jet scribing. In addition to etching the vias, it may be useful to etch along the cutting lines prior to using the wafer saw or other separation method to reduce the stress on the wavelength converter layer during the cutting step.

It will be appreciated that a wavelength converted LED device is not restricted to having one type of extraction feature, but may use multiple types of extraction features at different points within the device. For example, extraction features may be provided at any or all of the following: the side of the LED semiconductor layers facing away from the wavelength converter, the side of the semiconductor layers facing the wavelength converter, the side of the wavelength converter facing the LED and the side of the wavelength converter facing away from the LED. The light extraction features may also be provided at other points within the LED and the wavelength converter.

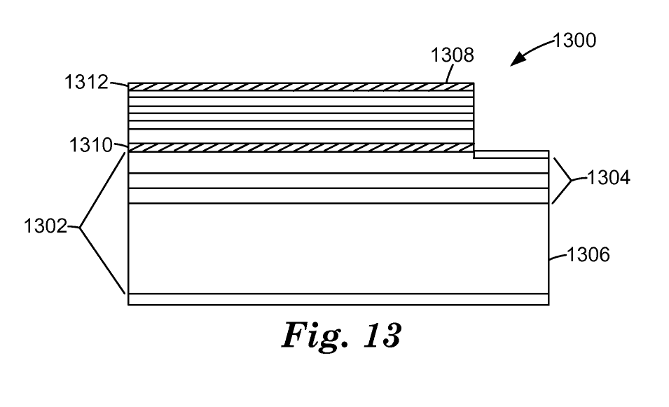

One example of a wavelength converted LED device 1300 having light extraction features at more than one position within the device is schematically illustrated in FIG. 13. The device 1300 is formed of an LED 1302, having LED semiconductor layers 1304 on an LED substrate 1306, optically bonded to a wavelength converter 1308. In this particular embodiment, the upper side of the LED 1302, facing the wavelength converter 1308, is provide with a first light extraction feature 1310, and the upper side of the wavelength converter 1308 is provide with a second light extraction feature 1312. The light extraction features 1310 and 1310 may be textured surfaces, scattering layers or a combination of the two, or any other suitable type of light extraction feature that is effective at extracting light from the LED 1302 and the wavelength converter 1308.

The present invention should not be considered limited to the particular examples described above, but rather should be understood to cover all aspects of the invention as fairly set out in the attached claims. Various modifications, equivalent processes, as well as numerous structures to which the present invention may be applicable will be readily apparent to those of skill in the art to which the present invention is directed upon review of the present specification. The claims are intended to cover such modifications and devices. For example, while the above description has discussed GaN-based LEDs, the invention is also applicable to LEDs fabricated using other III-V semiconductor materials, and also to LEDs that use II-VI semiconductor materials.

We claim:

1. A wavelength converted light emitting diode (LED) device, comprising:
an LED having an output surface; and
a multilayer semiconductor wavelength converter optically bonded to the LED, at least one of the LED and the wavelength converter being provided with light extraction features.

2. A device as recited in claim 1, wherein the light extraction features comprise a textured surface.

3. A device as recited in claim 2, wherein the textured surface is a surface of the LED.

4. A device as recited in claim 2, wherein the textured surface is a surface of the wavelength converter.

5. A device as recited in claim 1, wherein the light extraction features comprise a plurality of light scattering particles.

6. A device as recited in claim 5, wherein the LED comprises the light scattering particles.

7. A device as recited in claim 5, wherein the wavelength converter comprises the light scattering particles.

8. A device as recited in claim 1, wherein the wavelength converter is directly bonded to the LED.

9. A device as recited in claim 1, wherein the wavelength converter is bonded to the LED via an evanescent bonding layer.

10. A device as recited in claim 1, wherein the LED comprises LED semiconductor layers attached to an LED substrate, the light extraction features being provided in at least one of the LED semiconductor layers and the LED substrate.

11. A device as recited in claim 10, wherein the LED semiconductor layers are attached to the LED substrate via a metal layer, and the light extraction features are located at a side of the LED semiconductor layers proximate the metal layer.

12. A device as recited in claim 1, wherein the light extraction features are provided within an evanescent coupling distance of a material interface within the device.

13. A method of making wavelength converted, light emitting diodes, comprising:
providing a light emitting diode (LED) wafer comprising a set of LED semiconductor layers disposed on a substrate;
providing a multilayer semiconductor wavelength converter wafer configured to be effective at converting wavelength of light generated within the LED layers;
optically bonding the converter wafer to the LED wafer to produce an LED/converter wafer; and
separating individual converted LED dies from the LED/converter wafer.

14. A method as recited in claim 13, wherein optically bonding the converter wafer to the LED wafer comprises directly bonding the wavelength converter wafer to the LED wafer.

15. A method as recited in claim 13, wherein optically bonding the converter wafer to the LED wafer comprises bonding the wavelength converter wafer to the LED wafer via an evanescent bonding layer.

16. A method as recited in claim 13, further comprising providing light extraction features in one of the LED wafer and the wavelength converter wafer.

17. A method as recited in claim 16, wherein providing the light extraction features comprises providing a textured surface on one of the LED wafer and the wavelength converter wafer.

18. A method as recited in claim 16, wherein providing the light extraction features comprises providing light scattering particles within one of the LED wafer and the wavelength converter wafer.

19. A semiconductor wavelength converter device, comprising:
a multilayer semiconductor wavelength converter, the wavelength converter comprising light extraction features;
a removable protection layer on a first side of the wavelength converter, a second side of the wavelength converter being flat for optical bonding to another semiconductor element.

20. A device as recited in claim 19, wherein optically bonding the converter wafer to the LED wafer comprises directly bonding the wavelength converter wafer to the LED wafer.

21. A device as recited in claim 19, wherein the light extraction features comprise a textured surface.

22. A device as recited in claim 19, wherein the light extraction features comprise a scattering layer.

23. A device as recited in claim 19, wherein the light extraction features are provided on the first side of the wavelength converter.

24. A device as recited in claim 19, wherein the light extraction features are provided on the second side of the wavelength converter.
